(19) United States
(12) Patent Application Publication
(10) Pub. No.: US 2012/0161881 A1
(43) Pub. Date: Jun. 28, 2012

(54) Pure-silicon digital oscillator

(75) Inventors: Chung-Chih TUNG, Taipei City (TW); Ta-I LIU, Taipei City (TW)

(73) Assignee: Ta-I LIU

(21) Appl. No.: 13/408,982

(22) Filed: Feb. 29, 2012

Related U.S. Application Data
(63) Continuation-in-part of application No. 12/704,195, filed on Feb. 11, 2010.

(51) Int. Cl. H03L 7/00

(52) U.S. Cl. 331/34

(57) ABSTRACT

A pure-silicon digital oscillator includes a baseband generator for generating a standard baseband, and a clock pulse monitoring and modulating circuit for performing a frequency calibration to the standard baseband to produce a calibrated baseband, while storing an error value produced during the calibration into a data storage device, such that a frequency generator can generate an output frequency according to a numerical value of the calibrated baseband. After the output frequency is processed by a digital signal processing to form a digital output frequency to be inputted into a square wave generator, the square wave generator outputs a higher digital frequency according to the numerical value of the digital output frequency, and the higher digital frequency is provided for a digital power supply control device to drive currents and modulate voltages.

### CROSS-REFERENCES TO RELATED APPLICATIONS

This application is a continuation-in-part of my copending application Ser. No. 12/704,195 filed on Feb. 11, 2010.

### BACKGROUND OF THE INVENTION

1. Field of the Invention

Embodiments of the invention relate to a pure-silicon digital oscillator, and more particularly to a pure-silicon digital oscillator capable of performing a frequency modulation automatically in order to prevent frequency jitters of an output frequency.

2. Description of the Related Art

In the field of communications, a frequency close to the frequency of a clock pulse signal must be used at both data transmitting end and data receiving end to assure a correct data transmission. Such frequency requirement varies with different application areas. For example, the USB specification defines a maximum clock tolerance of ±500 ppm for a high speed mode and ±2,500 ppm for a full speed mode. In general, the higher data transmission rate, the stricter is the error requirement. To comply with the high-precision requirement, a quartz oscillator with a higher precision is generally used at both transmitting and receiving ends.

However, conventional quartz oscillators and other high-precision oscillators incur a higher cost and come with a high installation failure rate, and thus they cannot be attached to a circuit board by a surface mount technology (SMT) easily and usually result in a higher level of difficulty for the manufacture as well as a higher manufacturing cost. Obviously, the conventional oscillators require improvements.

### SUMMARY OF THE INVENTION

In view of the aforementioned shortcomings of the conventional quartz oscillator, the inventor of the present invention based on years of experience in the related industry to conduct extensive researches and experiments, and finally developed a pure-silicon digital oscillator in accordance with the present invention to overcome the shortcomings of the prior art.

Therefore, it is a primary objective of the present invention to provide a pure-silicon digital oscillator that adopts a semiconductor pure-silicon circuit as an oscillator circuit to overcome each of the aforementioned shortcomings of the conventional quartz oscillator.

Another objective of the present invention is to provide a pure-silicon digital oscillator capable of performing a frequency modulation automatically to prevent frequency jitters of an output frequency.

To achieve the foregoing objectives, the present invention has a baseband generator for generating a standard baseband that can be used for a frequency calibration by a clock pulse monitoring and modulating circuit to calibrate and produce a calibrated baseband, while storing an error value produced during the calibration into a data storage device, such that a frequency generator can generate an output frequency according to a numerical value of the calibrated baseband. After the output frequency is processed by a digital signal processor to form a digital output frequency to be inputted into a square wave generator, the square wave generator outputs a higher digital frequency according to the numerical value of the digital output frequency, wherein the higher digital frequency is provided for a digital power supply control device to drive currents and modulate voltages. With the frequency modulation and the digital processing, the digital frequency outputted by the square wave generator is free of frequency jitters, and the digital power supply control device can achieve a correct voltage modulation.

According to one embodiment, a pure-silicon digital oscillator comprises a baseband generator, a clock pulse monitoring and modulating circuit, a data storage device, a frequency generator, a digital signal processor and a square wave generator. The data storage device is provided for storing an error value and a desired frequency value for modulating and calibrating the standard fundamental oscillation frequency. The baseband generator is provided for generating a standard fundamental oscillation frequency and generates a calibrated baseband that adjusts the standard fundamental oscillation frequency based on the error value. The frequency generator is provided for generating an output frequency according to the calibrated baseband and the error value. The digital signal processor generates a digital output frequency according to the output frequency of the frequency generator. The square wave generator is provided for generating a digital waveform (i.e. a square wave) according to the digital output frequency. The clock pulse monitoring and modulating circuit is provided for modulating and calibrating the output frequency of the frequency generator.

Still other aspects, features and advantages of the invention are readily apparent from the following detailed description, simply by illustrating a number of particular embodiments and implementations, including the best mode contemplated for carrying out the invention. The invention is also capable of other and different embodiments, and its several details can be modified in various obvious respects, all without departing from the spirit and scope of the invention. Accordingly, the drawings and description are to be regarded as illustrative, and not as restrictive.

### BRIEF DESCRIPTION OF THE DRAWINGS

The invention is illustrated by way of example, and not by way of limitation, in the figures of the accompanying drawings in which like reference numerals refer to similar elements and in which:

FIG. 1 is a block diagram of a structure of the present invention; and

FIG. 2 is a schematic view of a frequency modulation of the present invention.

### DETAILED DESCRIPTION OF THE INVENTION

Devices and methods for coordinating power to an electronic load are disclosed. In the following description, for the purposes of explanation, numerous specific details are set forth in order to provide a thorough understanding of the invention. It is apparent, however, to one skilled in the art that the invention may be practiced without these specific details or with an equivalent arrangement. In other instances, well-known structures and devices are shown in block diagram form in order to avoid unnecessarily obscuring the embodiments of the invention.

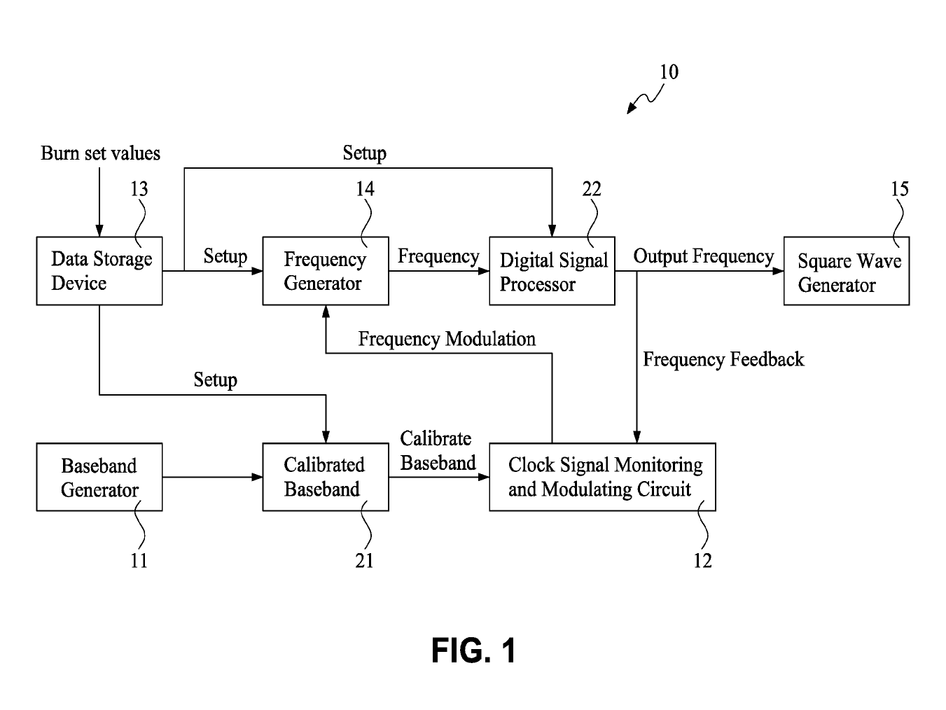

With reference to FIG. 1 for a pure-silicon digital oscillator in accordance with the present invention, the pure-silicon digital oscillator 10 comprises a baseband generator 11, a clock pulse monitoring and modulating circuit 12, a data storage device 13, a frequency generator 14, a digital signal processor 22 and a square wave generator 15.

The data storage device 13 is provided for storing an error value and a desired frequency value for modulating and calibrating the standard fundamental oscillation frequency. The baseband generator 11 is provided for generating a standard fundamental oscillation frequency and generates a calibrated baseband 21 that adjusts the standard fundamental oscillation frequency based on the error value. The frequency generator 14 is provided for generating an output frequency according to the calibrated baseband and the error value produced. The digital signal processor 22 generates a digital output frequency according to the output frequency of the frequency generator 14. The square wave generator 15 is provided for generating a digital waveform (i.e. a square wave) according to the digital output frequency. The digital waveform is provided for a digital power supply control device (not shown in the figure) to drive currents and modulate voltages. The clock pulse monitoring and modulating circuit 12 is provided for modulating and calibrating the output frequency of the frequency generator 14.

The data storage device 13 may be an electronic erasable programmable read only memory (EEPROM) for storing values during the modulation and calibration of the standard fundamental oscillation frequency.

The clock pulse monitoring and modulating circuit 12 comprises a monitoring module and a modulating module. The monitoring module monitors the digital output frequency of the digital signal processor 22, and counts a frequency of the digital output frequency within a period of the calibrated baseband 21. When the frequency of the output frequency excess or below the desired frequency value, it means the digital output frequency contains an error and thus the modulating module generates an adjusting signal to the frequency generator 14. The adjusting signal may be a pull high signal or a pull low signal.

In one embodiment, the pull high signal indicates the frequency generator 14 to increase the frequency of the output frequency. The pull low signal indicates the frequency generator 14 to decrease the frequency of the output frequency. The clock pulse monitoring and modulating circuit 12 can be easily performed by using logic gates combination that senses and compares the desired frequency value and the digital output frequency fed back from the digital signal processor 22. The implement of the logic gates is known by a person skilled in the art, and will not be addressed in the present disclosure.

When the frequency generator 14 receives the adjusting signal, the adjusting signal will indicate the frequency generator 14 referring the error value stored in the data storage device. The error value indicates the frequency generator 14 a predetermined amount of the frequency for increasing or decreasing the frequency of the output signal. The clock pulse monitoring and modulating circuit 12 is configured to repeat until the frequency of the digital output frequency has met the the desired frequency value.

With the frequency modulation and the digital processing, the digital frequency outputted by the square wave generator 15 is free of frequency jitters, and the digital power supply control device can achieve a correct voltage modulation.

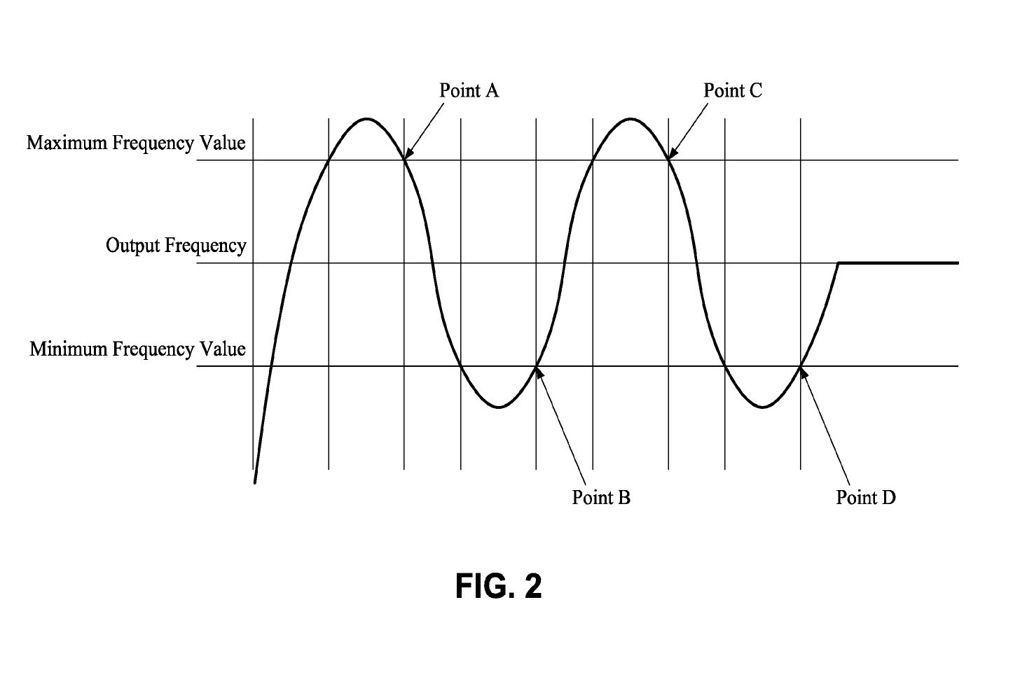

With reference to FIG. 2, the desired frequency value may be a range value that comprises a maximum value and a minimum value. In one example, if the clock pulse monitoring and modulating circuit 12 is used for a frequency calibration, a digital frequency feedback is calculated after the baseband is calibrated. If the digital output frequency feedback reaches the maximum or minimum value, the clock pulse monitoring and modulating circuit 12 will notice the frequency generator 14 to carry out a modulation. On the other hand, no action will be taken if the frequency falls within an acceptable range. In FIG. 2, Points A and C exceeding the maximum value and Points B and D exceeding the minimum value will be eliminated, and the values remained within the acceptable range are averaged to obtain the frequency, so as to achieve the effect of a constant frequency output.

In summation of the description above, the foregoing standard baseband is used for generating a calibrated baseband, which is obtained at a standard time after the feedback frequency is calculated. In the standard baseband, there is a temperature deviation issue, and thus the digital processing method is provided for processing the produced baseband, such that the temperature deviation and/or other issues will not result in a frequency error (wherein the standard frequency-temperature error value remains below 15000 PPM), and such frequency error will be stored back into the EEPROM during a production testing procedure, so that an error occurred during the production process can be avoided.

While the invention has been described in connection with a number of embodiments and implementations, the invention is not so limited but covers various obvious modifications and equivalent arrangements, which fall within the purview of the appended claims. Although features of the invention are expressed in certain combinations among the claims, it is contemplated that these features can be arranged in any combination and order.

What is claimed is:

1. A pure-silicon digital oscillator, comprising:
a data storage device storing an error value and a desired frequency value;
a baseband generator generating a standard fundamental oscillation frequency and a calibrated baseband that adjusts the standard fundamental oscillation frequency based on the error value;
a frequency generator generating an output frequency according to the calibrated baseband and the error value;
a digital signal processor generating a digital output frequency according to the output frequency of the frequency generator; and
a clock pulse monitoring and modulating circuit modulating and calibrating the output frequency of the frequency generator, and comprising
a monitoring module counting a frequency of the digital output frequency within a period of the calibrated baseband; and
a modulating module generates an adjusting signal to the frequency generator when the output frequency excess or below the desired frequency value.

2. The pure-silicon digital oscillator as claimed in claim 1, wherein the adjusting signal is a pull high signal, the pull high signal indicates the frequency generator to increase the frequency of the output frequency, and the error value indicates the frequency generator a predetermined amount of the frequency for increasing the frequency of the output signal.

3. The pure-silicon digital oscillator as claimed in claim 1, wherein the adjusting signal is a pull low signal, the pull low signal indicates the frequency generator to decrease the frequency of the output frequency, and the error value indicates the frequency generator a predetermined amount of the frequency for decreasing the frequency of the output signal.

4. The pure-silicon digital oscillator as claimed in claim 1, wherein the clock pulse monitoring and modulating circuit is a logic gates combination.

5. The pure-silicon digital oscillator as claimed in claim 1, wherein the data storage device is an electronic erasable programmable read only memory (EEPROM).

6. The pure-silicon digital oscillator as claimed in claim 1, wherein the desired frequency value is a range value that comprises a maximum value and a minimum value, the clock pulse monitoring and modulating circuit informs the frequency generator to carry out a modulation when the digital output frequency is excesses the maximum value or below the minimum value.

7. The pure-silicon digital oscillator as claimed in claim 6, wherein the clock pulse monitoring and modulating circuit takes no action when the frequency of the digital output frequency within the range value.
